(19) United States
(12) Patent Application Publication
(10) Pub. No.: US 2017/0200782 A1
(43) Pub. Date: Jul. 13, 2017

(54) CAPACITOR OF SEMICONDUCTOR INTEGRATED CIRCUIT AND METHOD FOR MANUFACTURING THE SAME

(71) Applicant: Amkor Technology, Inc., Tempe, AZ (US)

(72) Inventors: Han Min Lee, Gyeongju-si (KR); Pan Ju Choi, Gwangju (KR); Kwang Sun Oh, Gwangju (KR); Sung Man Hong, Gwangju (KR); Sung Woong Hong, Gwangju (KR); Kyung Han Ryu, Seongnam-si (KR)

(21) Appl. No.: 15/149,054

(22) Filed: May 6, 2016

(30) Foreign Application Priority Data
Jan. 11, 2016 (KR) 10-2016-0003347

(51) Int. Cl. H01L 49/02; H01L 21/3205; H01L 21/02

(52) U.S. Cl. CPC H01L 28/75; H01L 21/02271; H01L 21/32051

(57) ABSTRACT

Provided are a capacitor of a semiconductor integrated circuit and a method for manufacturing the same, for example a metal-insulator-metal (MIM) type capacitor of a semiconductor integrated circuit, which is capable of improving adhesive force between an electrode layer and a dielectric layer of a capacitor, and a method for manufacturing the same. For example, the present disclosure provides a capacitor for a semiconductor integrated circuit having a new structure, which is capable of preventing a delamination phenomenon on an interface between a lower electrode layer and a dielectric layer by further forming a buffer layer, which is capable of decreasing or compensating for a difference in a coefficient of thermal expansion, between a metal electrode layer and a dielectric layer, particularly, between the lower electrode layer and the dielectric layer, and a method for manufacturing the same.

### CROSS-REFERENCE TO RELATED APPLICATIONS

The present application makes reference to, claims priority to, and claims the benefit of Korean Patent Application No. 10-2016-0003347, filed on Jan. 11, 2016, the contents of which are hereby incorporated herein by reference, in their entirety.

### FIELD

Contained embodiments of the disclosure relate to a capacitor of a semiconductor integrated circuit and a method for manufacturing the same, and more particularly, to a metal-insulator-metal type capacitor of a semiconductor integrated circuit, which is capable of improving adhesive force between an electrode layer and a dielectric layer of the capacitor, and a method for manufacturing the same.

### BACKGROUND

In general, a semiconductor integrated circuit (for example, a memory device) is divided into a digital integrated circuit and an analog integrated circuit according to a signal processing method, and it is known that every integrated circuit records information according to existence and non-existence of charges accumulated in a capacitor regardless of a digital type and an analog type.

The capacitor is a sort of semiconductor device storing energy, and is manufactured in a structure, in which two electrode layers and a dielectric layer disposed between the electrode layers are laminated.

Accordingly, when a DC voltage (for example, a positive voltage) is applied to one electrode layer, positive charges are accumulated in the one charged electrode layer, and negative charges are accumulated in the opposite electrode layer, in such a manner that the charges are accumulated so as to be balanced with the applied voltage, so that the capacitor is in a charging completed state, and the current in this state is in a cut-off state.

On the other hand, a discharge of the capacitor is a reverse process of the charging process, and when resistance is connected instead of applying a voltage, charges are discharged as much as the charged amount, so that a current becomes a flowing state, and further, the processes of the charging and the discharging are repeated at an AC voltage, so that the current is always in a flowing state through the capacitor.

A structure of a capacitor of a semiconductor integrated circuit performing the aforementioned function in the related art will be described below.

FIG. 1 illustrates a structure of a capacitor in the related art.

As illustrated in FIG. 1, a capacitor 20 includes a lower electrode layer 12, which is formed on a wafer 10 (for example, silicon or glass) and is made of a metal (for example, copper), a dielectric layer 14 (for example, silicon nitride (SiN)) formed on the lower electrode layer 12, and an upper electrode layer 16, which is formed on the dielectric layer 14 and is made of a metal (for example, copper), so that the capacitor 20 generally has a metal-insulator-metal (MIM) type structure.

The capacitor in the related art is manufactured by a process below.

First, a first seed layer 11 (titanium-tungsten (TiW) layer) for plating the lower electrode layer is coated on the wafer 10 by using a sputtering method.

Subsequently, the lower electrode layer 12 made of a metal (for example, copper) is formed on the first seed layer 11 by using a typical plating process.

Next, a silicon nitride (SiN) is coated on the lower electrode layer 12 as the dielectric layer 14 by using a plasma-enhanced chemical vapor deposition (PECVD) method.

Subsequently, a second seed layer 15 (titanium-tungsten (TiW) layer) for plating the upper electrode layer is coated on the dielectric layer 14 by using a sputtering method.

Subsequently, the upper electrode layer 16 made of a metal (for example, copper) is formed on the second seed layer 15 by using a typical plating process.

By sequentially performing the aforementioned processes, the MIM type capacitor in the related art, in which the lower electrode layer 12, the dielectric layer 14, and the upper electrode layer 16 are sequentially laminated, is completed.

Accordingly, when a voltage is applied to the lower electrode layer 12, positive charges are accumulated and negative charges are accumulated in the opposite upper electrode layer 16, so that the capacitor is charged, and a discharge of the capacitor is a reverse process of the charging process, and when resistance is applied instead of a voltage, the charges are discharged and a current becomes a flowing state.

However, the MIM type capacitor in the related art has the problems below.

A delamination phenomenon occurs on an interface between an electrode layer and a dielectric layer due to a mismatch of a coefficient of thermal expansion (CTE) between the electrode layer and the dielectric layer configuring the capacitor.

The manufacturing process of the capacitor goes through the processes, such as plating, sputtering, and PECVD, thereby thermally influencing each configuration, and a CTE of the upper and lower electrode layers (for example, copper) is 16 to 18 ppm/° C., a CTE of the dielectric layer (for example, SiN) is 2.1 to 3.1 ppm/° C., and a CTE of the first and second seed layers (for example, TiW) is 4.5 to 4.6 ppm/° C.

Accordingly, as illustrated in FIG. 1, the upper electrode layer 16 is in contact with the dielectric layer 14 with the second seed layer 15 interposed therebetween, so that interface delamination between the upper electrode layer 16 and the dielectric layer 14 does not occur well, but the lower electrode layer 12 is directly in contact with the dielectric layer 14, so that the delamination phenomenon occurs on the interface between the lower electrode layer 12 and the dielectric layer 14 due to an excessively large difference in a CTE of the lower electrode layer 12 and the dielectric layer 14.

### BRIEF SUMMARY

The present disclosure provides a capacitor for a semiconductor integrated circuit having a new structure, which prevents a delamination phenomenon on an interface between a lower electrode layer and a dielectric layer by further forming a buffer layer, which is capable of decreasing or compensating for a difference in a coefficient of thermal expansion, between the metal electrode layer and the dielectric layer, particularly, the lower electrode layer and the dielectric layer, and a method for manufacturing the same.

The above and other objects of the present disclosure will be described in or be apparent from the following description of the preferred embodiments.

According to an aspect of the present disclosure, there is provided a capacitor for a semiconductor integrated circuit, including: a lower electrode layer formed on a wafer with a first seed layer interposed therebetween; a dielectric layer formed on the lower electrode layer; and an upper electrode layer formed on the dielectric layer with a second seed layer interposed therebetween, in which a buffer layer for decreasing a difference in a coefficient of thermal expansion between the lower electrode layer and the dielectric layer is further formed between the lower electrode layer and the dielectric layer.

The buffer layer may be formed of any one material selected from TiW, Ti, Cr, and W.

The dielectric layer may be coated with any one selected from a silicon nitride SiN, an aluminum oxide (Al₂O₃), and a hafnium oxide (HfO₃).

According to an aspect of the present disclosure, there is provided a method of manufacturing a capacitor for a semiconductor integrated circuit, the method sequentially including: i) coating a first seed layer for plating a lower electrode layer on a wafer; ii) plating a lower electrode layer made of a metal on the first seed layer; iii) coating a buffer layer for decreasing a difference in a coefficient of thermal expansion between the lower electrode and a dielectric layer on the lower electrode layer; iv) coating the dielectric layer on the buffer layer; v) coating a second seed layer for plating an upper electrode layer on the dielectric layer; and vi) plating the upper electrode layer made of a metal on the second seed layer.

The buffer layer may be formed of any one material selected from TiW, Ti, Cr, and W, and may be coated on the lower electrode layer by a sputtering method.

The dielectric layer may be coated with any one selected from a silicon nitride SiN, an aluminum oxide (Al₂O₃), and a hafnium oxide (HfO₃), and may be coated on the buffer layer by a plasma-enhanced chemical vapor deposition (PECVD).

Through the aforementioned technical solutions, the present disclosure provides the effects below.

According to the present disclosure, it is possible to decrease a difference in a coefficient of thermal expansion between the lower electrode layer and the dielectric layer and easily prevent a delamination phenomenon on an interface between the lower electrode layer and the dielectric layer by forming the buffer layer, which is capable of decreasing a difference in a coefficient of thermal expansion, between the metal electrode layer and the dielectric layer of the capacitor, particularly, between the lower electrode layer and the dielectric layer.

### BRIEF DESCRIPTION OF SEVERAL VIEWS OF THE DRAWINGS

FIG. 1 is a cross-sectional view illustrating a structure of a capacitor of a semiconductor integrated circuit in the related art.

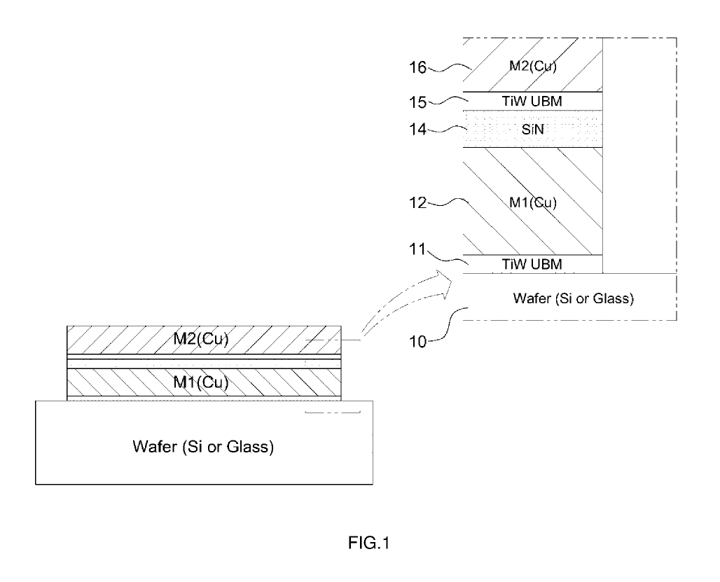

FIG. 2 is a cross-sectional view illustrating a structure of a capacitor of a semiconductor integrated circuit according to the present disclosure.

FIG. 3 is actual images of the comparison of the capacitor in the related art and the capacitor of the present disclosure by an electron microscope.

### DETAILED DESCRIPTION

Hereinafter, an exemplary embodiment of the present disclosure will be described in detail with reference to the accompanying drawings.

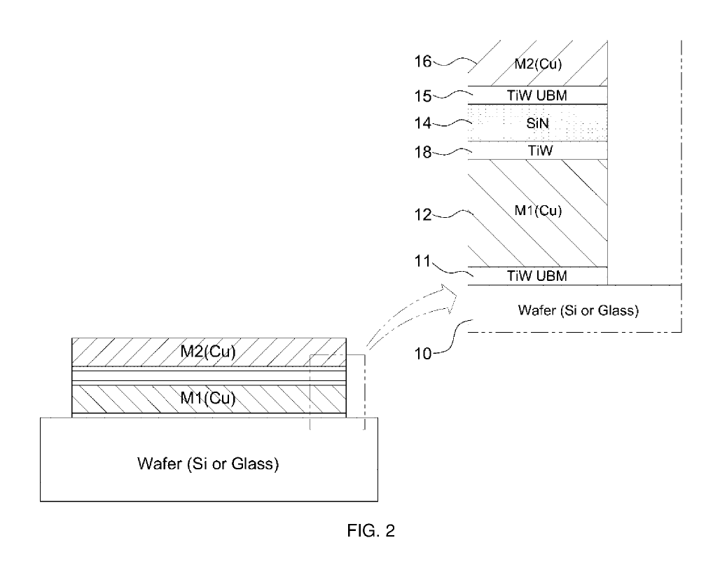

FIG. 2 is a cross-sectional view illustrating a structure of a capacitor of a semiconductor integrated circuit according to the present disclosure.

As illustrated in FIG. 2, a capacitor 20 according to the present disclosure has a metal-insulator-metal (MIM) type structure including a lower electrode layer 12, which is formed on a wafer 10 (for example, silicon or glass) and is made of a metal (for example, copper), a dielectric layer 14 (for example, silicon nitride (SiN)) formed on the lower electrode layer 12, and an upper electrode layer 16, which is formed on the dielectric layer 14 and is made of a metal (for example, copper), and a buffer layer 18, which is capable of decreasing a difference in a coefficient of thermal expansion between the respective metal electrodes 12 and 16 and the dielectric layer 14, particularly, the lower electrode layer 16 and the dielectric layer 14, is further formed.

The capacitor of the present disclosure is manufactured by a process below.

First, a first seed layer (titanium-tungsten (TiW) layer) for plating the lower electrode layer is coated on the wafer 10 by using a sputtering method.

Subsequently, the lower electrode layer 12 made of a metal (for example, copper) is formed on the first seed layer 11 by using a typical plating process.

Subsequently, the buffer layer 18, which is capable of decreasing a difference in a coefficient of thermal expansion between the lower electrode layer 12 and the dielectric layer 14, is coated on a surface of the lower electrode layer 12 by using a sputtering method.

The buffer layer 18 may be made of TiW, which is the same as the material of the first and second seed layers (TiW) used during the process of manufacturing the capacitor, as a material, which is capable of decreasing a difference in a coefficient of thermal expansion between the lower electrode layer 12 and the dielectric layer 14, but the material of the buffer layer 18 is not limited to TiW, and a material, such as Ti, Cr, and W, may be used considering a coefficient of thermal expansion and an electric characteristic.

Accordingly, any one selected from TiW, Ti, Cr, and W is adopted as the buffer layer 18 and is coated on the lower electrode layer 12 by the sputtering method.

Next, a silicon nitride (SiN) is coated on the lower electrode layer 12 as the dielectric layer 14 by using a plasma-enhanced chemical vapor deposition (PECVD) method.

Otherwise, an aluminum oxide (Al₂O₃) or a hafnium oxide (HfO₃) is coated on the lower electrode layer 12 as the dielectric layer 14 by using a PECVD method in order to improve a capacitance density.

Subsequently, a second seed layer 15 (titanium-tungsten (TiW) layer) for plating the upper electrode layer is coated on the dielectric layer 14 by using a sputtering method.

Subsequently, the upper electrode layer 16 made of a metal (for example, copper) is formed on the second seed layer 15 by using a typical plating process.

By sequentially performing the aforementioned processes, the MIM type capacitor in the related art, in which the lower electrode layer 12, the dielectric layer 14, and the upper electrode layer 16 are sequentially laminated, is completed, and the buffer layer 18 is present between the lower electrode layer 12 and the dielectric layer 14, and the second seed layer 15 made of the same material as that of the buffer layer is present between the dielectric layer 14 and the upper electrode layer 16, so that it is possible to decrease a difference in a coefficient of thermal expansion between the respective electrode layers 12 and 16 and the dielectric layer 14, particularly, the lower electrode layer 12 and the dielectric layer 14, thereby easily preventing a delamination phenomenon on an interface of the lower electrode layer 12 and the dielectric layer 14.

A coefficient of thermal expansion of the lower and upper electrode layers 12 and 16 is 16 to 18 ppm/° C., a coefficient of thermal expansion of the dielectric layer (for example, SiN) is 2.1 to 3.1 ppm/° C., a coefficient of thermal expansion of the first and second seed layers (for example, TiW) is 4.5 to 4.6 ppm/° C., and a coefficient of thermal expansion of the buffer layer (for example, TiW) is also 4.5 to 4.6 ppm/° C.

Accordingly, in the related art, the lower electrode layer 12 is directly in contact with the dielectric layer 14, so that there is a problem in that a delamination phenomenon occurs on the interface between the lower electrode layer 12 and the dielectric layer 14 due to the excessively large difference in a coefficient of thermal expansion between the lower electrode layer 12 and the dielectric layer 14. However, in the present disclosure, the buffer layer 18 present between the lower electrode layer 12 and the dielectric layer 14 serves to decrease a difference in a coefficient of thermal expansion between the lower electrode layer 12 and the dielectric layer 14, thereby easily preventing a delamination phenomenon on an interface between the lower electrode layer 12 and the dielectric layer 14.

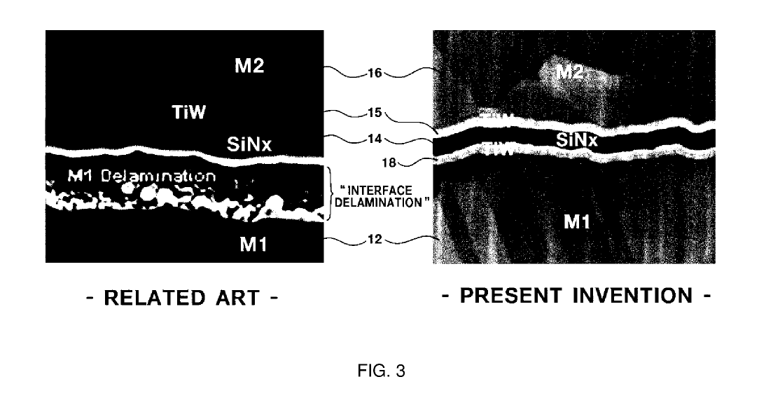

As a test example of the present disclosure, cross-sections of the capacitor of the present disclosure including the buffer layer as described above and the capacitor in the related art were observed by using an electron microscope, and the result is illustrated in FIG. 3.

As can be seen in FIG. 3, it is observed that a delamination phenomenon occurs on the interface between the lower electrode layer 12 and the dielectric layer 14 in the capacitor in the related art, but in the present disclosure, the interface between the lower electrode layer 12 and the dielectric layer 14 is firmly bonded without delamination by the buffer layer 18 present between the lower electrode layer 12 and the dielectric layer 14.

1. A semiconductor integrated circuit, comprising:
a substrate comprising a substrate coefficient of thermal expansion (CTE); and
a capacitor on the substrate and comprising:
a lower seed layer on a topmost substrate surface of the substrate and comprising a lower seed CTE;
a lower electrode layer on the lower seed layer and comprising a lower electrode CTE;
a buffer layer on the lower electrode layer and comprising a buffer CTE;
a dielectric layer on the buffer layer and comprising a dielectric CTE;
an upper seed layer on the dielectric layer and comprising an upper seed CTE; and
an upper electrode layer on the upper seed layer and comprising an upper electrode CTE;
wherein:
the lower electrode CTE is greater than the buffer CTE;
the buffer CTE is greater than the dielectric CTE;
the lower electrode CTE is greater than the lower seed CTE;
the lower seed CTE is greater than the substrate CTE;
the upper electrode CTE is greater than the upper seed CTE;
the upper seed CTE is greater than the dielectric CTE; and
a difference between the lower electrode CTE and the buffer CTE is greater than a difference between the buffer CTE and the dielectric CTE.

2. The semiconductor integrated circuit of claim 1, wherein:
the substrate comprises one or both of a semiconductor material and/or a glass material;
each layer of the capacitor is formed on the substrate;
materials of the lower seed layer, of the buffer layer, and of the upper seed layer are the same as each other;
the lower seed layer comprises a plated layer onto the topmost substrate surface;
the lower electrode layer comprises a plated layer plated onto the lower seed layer;
the buffer layer comprises a sputtered layer sputtered onto the lower electrode layer;
the dielectric layer comprises a chemical vapor deposition layer deposited onto the buffer layer;
the upper seed layer comprises a plated layer plated onto the dielectric layer; and
the upper electrode layer comprises a plated layer plated onto the upper seed layer.

3. A semiconductor integrated circuit, comprising:
a substrate; and
a capacitor on the substrate and comprising:
a lower electrode layer coupled to the substrate and comprising a lower electrode coefficient of thermal expansion (CTE);
a buffer layer on the lower electrode layer and comprising a buffer CTE;
a dielectric layer on the buffer layer and comprising a dielectric CTE; and
an upper electrode layer on the dielectric layer;
wherein:
the lower electrode CTE is greater than the buffer CTE; and
the buffer CTE is greater than the dielectric CTE.

4. The semiconductor integrated circuit of claim 3, wherein:
the buffer layer comprises one or more of:
titanium-tungsten (TiW), titanium (Ti), chrome (Cr), and/or tungsten (W).

5. The semiconductor integrated circuit of claim 3, wherein:
the dielectric layer comprises one or more of:
silicon nitride (SiN), aluminum oxide (Al2O3), and/or hafnium oxide (HfO3).

6. The semiconductor integrated circuit of claim 3, wherein:
each layer of the capacitor is formed on the substrate.

7. The semiconductor integrated circuit of claim 3, wherein:
the substrate comprises one or both of a semiconductor material and/or a glass material.

8. The semiconductor integrated circuit of claim 3, wherein:
a difference between the lower electrode CTE and the buffer CTE is greater than a difference between the buffer CTE and the dielectric CTE.

9. The semiconductor integrated circuit of claim 3, comprising:
a lower seed layer between the substrate and the lower electrode layer and comprising a lower seed CTE;
wherein:
the lower electrode CTE is greater than the lower seed CTE; and
the lower seed CTE is greater than a CTE of the substrate.

10. The semiconductor integrated circuit of claim 9, wherein:
materials of the lower seed layer and of the buffer layer are the same as each other.

11. The semiconductor integrated circuit of claim 9, comprising:
an upper seed layer between the dielectric layer and the upper electrode layer and comprising an upper seed CTE;
wherein:
the upper electrode CTE is greater than the upper seed CTE; and
the upper seed CTE is greater than the dielectric CTE.

12. The semiconductor integrated circuit of claim 11, wherein:
materials of the lower seed layer, of the buffer layer, and of the upper seed layer are the same as each other.

13. The semiconductor integrated circuit of claim 3, wherein:
the buffer layer comprises a sputtered layer sputtered onto the lower electrode layer.

14. A method of manufacturing a capacitor for a semiconductor integrated circuit, the method comprising:
providing a substrate; and
forming a capacitor on the substrate, said forming comprising:
forming a lower electrode layer on the substrate;
forming a buffer layer on the lower electrode layer;
forming a dielectric layer on the buffer layer; and
forming an upper electrode layer on the second seed layer;
wherein:
the lower electrode CTE of the lower electrode layer is greater than a buffer CTE of the buffer layer; and
the buffer CTE is greater than a dielectric CTE of the dielectric layer.

15. The method of claim 14, wherein:
the buffer layer is sputtered onto the lower electrode layer and comprises one or more of titanium-tungsten (TiW), titanium (Ti), chrome (Cr), and/or tungsten (W).

16. The method of claim 14, wherein:
the dielectric layer is formed by chemical vapor deposition onto the buffer layer and comprises one or more of silicon nitride (SiN), aluminum oxide (Al2O3), and/or hafnium oxide (HfO3).

17. The method of claim 14, wherein:
forming the capacitor comprises plating a lower seed layer on the substrate; and
forming the lower electrode layer comprises plating the lower electrode layer on the lower seed layer.

18. The method of claim 17, wherein:
forming the capacitor comprises plating an upper seed layer on the dielectric layer; and
forming the upper electrode layer comprises plating the upper electrode layer on the upper seed layer.

19. The method of claim 18, wherein:
a material of the buffer layer is same as at least one of:
a material the upper seed layer; or
a material of the lower seed layer.

20. The method of claim 1, wherein:
forming the lower electrode layer comprises:
forming the lower electrode layer above a topmost surface of the substrate.
